(19) United States
(12) Patent Application Publication
(10) Pub. No.: US 2025/0221249 A1
(43) Pub. Date: Jul. 3, 2025

(54) Display Device

(71) Applicant: LG Display Co., Ltd., Seoul (KR)

(72) Inventors: Jooho Lee, Goyang-si (KR); Kwangsoo Kim, Incheon (KR); Wooyeong Jang, Seoul (KR)

(21) Appl. No.: 18/884,672

(22) Filed: Sep. 13, 2024

(30) Foreign Application Priority Data
Dec. 29, 2023 (KR) 10-2023-0197263

(51) Int. Cl. H10K 59/80

(52) U.S. Cl. CPC H10K 59/872; H10K 59/8722; H10K 59/8793

(57) ABSTRACT

Disclosed is a display device including a display panel including at least one hole defined in a display area, a cover member disposed on the display panel, a sealing member supporting an edge of the cover member and surrounding side surfaces of the display panel, and a stress relief member disposed adjacent to the at least one hole and disposed between the scaling member and a side surface of the display panel.

### CROSS-REFERENCE TO RELATED APPLICATION

This application claims priority from Republic of Korea Patent Application No. 10-2023-0197263 filed on Dec. 29, 2023, which is incorporated by reference in its entirety.

### BACKGROUND

### Field

The present disclosure relates to a display device, wherein the display device has a hole for an optical element defined therein.

### Description of Related Art

Specific examples of a flat display device include a liquid crystal display device, an organic light emitting display device, an inorganic light emitting display device, a quantum dot display device, and the like.

In an existing display device, a camera and various optical sensors were disposed in a bezel area of a display panel to perform various functions such as photo taking, facial recognition, and infrared light distance measurement in addition to image display.

Recently, technologies to place the camera and the optical sensors inside a display area of the display panel to minimize the bezel area are being developed.

As one of such technologies, a display device with a hole-in display (HID) structure, which defines a hole in the display area of the display panel to place the camera and the optical sensors, has been developed.

### SUMMARY

A fine cutting process may be performed typically using a laser to remove a display panel to define a hole in a display area. Cracks may be created around the hole in the display panel because of energy accumulated in a substrate during or after the cutting process.

The cracks created around the hole in the display panel may grow or spread into the display panel because of stress that occurs as the process progresses. In particular, the cracks may easily spread into the display panel via an inorganic insulating film disposed near the hole area of the display panel.

The cracks created around the hole in the display panel may become a path for external moisture to penetrate. Light emitting elements arranged in the display area are vulnerable to the moisture because they have an organic material layer or an organic light emitting layer. Specifically, when the moisture penetrates the organic material layer or the organic light emitting layer of the light emitting element, an organic material and the moisture may react with each other, causing screen defects such as a dark spot defect where a pixel does not completely emit light.

Accordingly, the inventors of the present disclosure developed a new structure that may reduce or prevent the growth or the spreading of the cracks created around the hole in the display panel.

An embodiment of the present disclosure is to provide a display device in which growth or spreading of cracks created around a hole of a display panel having the hole for an optical element may be reduced or prevented.

Purposes according to the present disclosure are not limited to the above-mentioned purpose. Other purposes and advantages according to the present disclosure that are not mentioned may be understood based on following descriptions, and may be more clearly understood based on embodiments according to the present disclosure. Further, it will be easily understood that the purposes and advantages according to the present disclosure may be realized using means shown in the claims or combinations thereof.

A display device according to an embodiment of the present disclosure includes a display panel including a display area and a non-display area around the display area, wherein the display panel includes at least one hole defined in the display area, a cover member disposed on the display panel, a sealing member supporting an edge of the cover member and in contact with a side surface of the display panel, and a stress relief member disposed adjacent to the at least one hole and disposed between the sealing member and a side surface of the display panel.

A display device according to an embodiment of the present disclosure includes a display panel including at least one hole defined in a display area, a sealing member surrounding side surfaces of the display panel, and at least one stress relief member disposed adjacent to the at least one hole and disposed between the sealing member and a side surface of the display panel, wherein the stress relief member has a thermal expansion coefficient lower than a thermal expansion coefficient of the sealing member.

Specific details of other embodiments are included in the detailed description and drawings.

According to the embodiments of the present disclosure, as the at least one stress relief member is disposed between the sealing member and the upper side surface of the display panel, the stress applied to the area adjacent to the upper side surface of the display panel resulted from the thermal expansion and contraction of the sealing member may be relieved, and in particular, the stress applied to the area around the at least one hole in the display panel may be relieved.

Accordingly, the deformation around the at least one hole of the display panel resulted from the thermal expansion and contraction of the sealing member may be reduced or prevented, and the cracks created around the at least one hole of the display panel may be prevented from growing and spreading.

As a result, the screen defect of the display device caused by the penetration of the moisture and the corrosion or the electric corrosion of the wiring via the cracks created around the at least one hole of the display panel may be prevented.

Additionally, because the reliability and the lifespan of the display device may be improved, energy for producing the display device and greenhouse gas may be reduced.

Effects of the present disclosure are not limited to the above-mentioned effects, and other effects as not mentioned will be clearly understood by those skilled in the art from following descriptions.

### BRIEF DESCRIPTION OF THE DRAWINGS

FIG. 1 is a plan view schematically showing a display device according to an embodiment of the present disclosure.

FIG. 2 is a bottom view schematically showing a display device according to an embodiment of the present disclosure.

FIG. 3 is an enlarged view of A in FIG. 2 according to an embodiment of the present disclosure.

FIG. 4 is a cross-sectional view taken along a line 4-4 in FIG. 3 according to an embodiment of the present disclosure.

FIG. 5 is a cross-sectional view schematically showing a sub-pixel of a display device according to an embodiment of the present disclosure.

FIG. 6 is a diagram corresponding to FIG. 3 and schematically shows a display device according to another embodiment of the present disclosure.

FIG. 7 is a cross-sectional view taken along a line 7-7 in FIG. 6 according to an embodiment of the present disclosure.

FIG. 8 is a graph showing principal stress applied to an area around a hole of a display device according to Comparative Example and Present Examples.

FIG. 9 is a graph showing stress distribution of an area around a hole of a display device according to Comparative Example and Present Example.

### DETAILED DESCRIPTION

Advantages and features of the present disclosure, and a method of achieving the advantages and features will become apparent with reference to embodiments described later in detail together with the accompanying drawings. However, the present disclosure is not limited to the embodiments as disclosed under, but may be implemented in various different forms. Thus, these embodiments are set forth only to make the present disclosure complete, and to completely inform the scope of the present disclosure to those of ordinary skill in the technical field to which the present disclosure belongs.

For simplicity and clarity of illustration, elements in the drawings are not necessarily drawn to scale. The same reference numbers in different drawings represent the same or similar elements, and as such perform similar functionality. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure. Examples of various embodiments are illustrated and described further below. It will be understood that the description herein is not intended to limit the claims to the specific embodiments described. On the contrary, it is intended to cover alternatives, modifications, and equivalents as may be included within the spirit and scope of the present disclosure as defined by the appended claims.

A shape, a size, a ratio, an angle, a number, etc. disclosed in the drawings for illustrating embodiments of the present disclosure are illustrative, and the present disclosure is not limited thereto.

The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. It will be further understood that the terms “comprise”, “comprising”, “include”, and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of associated listed items. Expression such as “at least one of” when preceding a list of elements may modify the entire list of elements and may not modify the individual elements of the list. In interpretation of numerical values, an error or tolerance therein may occur even when there is no explicit description thereof.

In addition, it will also be understood that when a first element or layer is referred to as being present “on” a second element or layer, the first element or layer may be disposed directly on the second element or layer, or may be disposed indirectly on the second element or layer with a third element or layer being disposed between the first and second elements or layers.

It will be understood that when an element or layer is referred to as being “connected to”, or “connected to” another element or layer, it may be directly on, connected to, or connected to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present.

Further, as used herein, when a layer, film, region, plate, or the like is disposed “on” or “on a top” of another layer, film, region, plate, or the like, the former may directly contact the latter or still another layer, film, region, plate, or the like is disposed between the former and the latter. As used herein, when a layer, film, region, plate, or the like is directly disposed “on” or “on a top” of another layer, film, region, plate, or the like, the former directly contacts the latter and still another layer, film, region, plate, or the like is not disposed between the former and the latter. Further, as used herein, when a layer, film, region, plate, or the like may be disposed “below” or “under” another layer, film, region, plate, or the like, the former may directly contact the latter or still another layer, film, region, plate, or the like may be disposed between the former and the latter. As used herein, when a layer, film, region, plate, or the like is directly disposed “below” or “under” another layer, film, region, plate, or the like, the former directly contacts the latter and still another layer, film, region, plate, or the like is not disposed between the former and the latter.

In descriptions of temporal relationships, for example, temporal precedent relationships between two events such as “after”, “subsequent to”, “before”, etc., another event may occur therebetween unless “directly after”, “directly subsequent” or “directly before” is indicated.

When a certain embodiment may be implemented differently, a function or an operation specified in a specific block may occur in a different order from an order specified in a flowchart. For example, two blocks in succession may be actually performed substantially concurrently, or the two blocks may be performed in a reverse order depending on a function or operation involved.

It will be understood that, although the terms “first”, “second”, “third”, and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

The features of the various embodiments of the present disclosure may be partially or entirely combined with each other, and may be technically associated with each other or operate with each other. The embodiments may be implemented independently of each other and may be implemented together in an association relationship.

In interpreting a numerical value, the value is interpreted as including an error range unless there is separate explicit description thereof.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, “embodiments,” “examples,” “aspects, and the like should not be construed such that any aspect or design as described is superior to or advantageous over other aspects or designs.

Further, the term ‘or’ means ‘inclusive or’ rather than ‘exclusive or’. That is, unless otherwise stated or clear from the context, the expression that ‘x uses a or b’ means any one of natural inclusive permutations.

The terms used in the description below have been selected as being general and universal in the related technical field. However, there may be other terms than the terms depending on the development and/or change of technology, convention, preference of technicians, etc. Therefore, the terms used in the description below should not be understood as limiting technical ideas, but should be understood as examples of the terms for illustrating embodiments.

Further, in a specific case, a term may be arbitrarily selected by the applicant, and in this case, the detailed meaning thereof will be described in a corresponding description section. Therefore, the terms used in the description below should be understood based on not simply the name of the terms, but the meaning of the terms and the contents throughout the Detailed Descriptions.

Hereinafter, a display device according to an embodiment of the present disclosure will be described in detail with reference to the attached drawings.

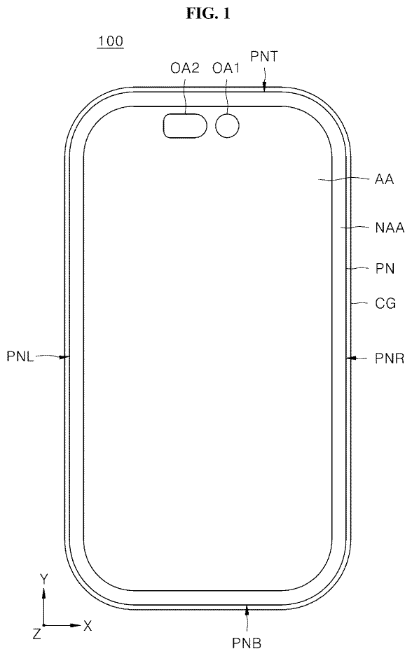

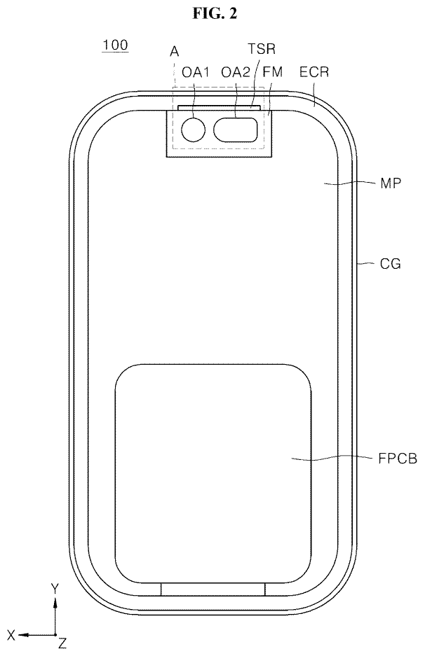

FIG. 1 is a plan view schematically showing a display device according to an embodiment of the present disclosure. FIG. 2 is a bottom view schematically showing a display device according to an embodiment of the present disclosure.

Referring to FIGS. 1 and 2, a display device 100 according to an embodiment of the present disclosure may include a display panel PN, a cover member CG disposed on the display panel PN, a sealing member ECR that supports an edge of the cover member CG and is in contact with a side surface of the display panel PN, and a stress relief member TSR disposed between the sealing member ECR and the display panel PN.

The display panel PN may include a display area AA in which a plurality of pixels are arranged and an image is displayed, and a non-display area NAA in which the image is not displayed.

Each pixel in the display area AA includes sub-pixels with different colors to render colors of the image. Each sub-pixel may include a light emitting element and a sub-pixel circuit for operating the light emitting element.

The non-display area NAA may be an area around the display area AA. Various signal lines may be disposed and various driving circuits may be connected or disposed in the non-display area NAA. The non-display area NAA may be an area that overlaps a bezel area of the display device 100 or a bezel area of the cover member CG.

The display device 100 may include a plurality of optical elements arranged under the display panel PN. At least one hole extending through the display panel PN may be defined within the display area AA of the display panel PN. The display panel PN may include at least one hole for at least one optical element within the display area AA. For example, a first hole OA1 and a second hole OA2 that extend through the display panel PN and are spaced apart from each other may be defined within the display area AA of the display panel PN. For example, the display panel PN may include the first hole OA1 and the second hole OA2 for the plurality of optical elements within the display area AA.

The first hole OA1 and the second hole OA2 of the display panel PN may be spaced apart from each other in a first direction parallel to an X-axis direction.

The display panel PN may include an upper side surface PNT, a lower side surface PNB, a left side surface PNL, and a right side surface PNR. For example, the upper side surface PNT of the display panel PN may be a surface of the display panel PN close to the first hole OA1 and the second hole OA2. The upper side surface PNT and the lower side surface PNB of the display panel PN may be located on opposite sides in a Y-axis direction. The left side surface PNL and the right side surface PNR of the display panel PN may be located on opposite sides in the X-axis direction.

The X-axis direction and the first direction parallel to the X-axis direction may be a direction parallel to the upper side surface PNT of the display panel PN. The Y-axis direction and a second direction parallel to the Y-axis direction may be a direction perpendicular to the upper side surface PNT of the display panel PN. The first direction and the second direction may be perpendicular to each other.

For example, an image sensor (or a camera) that captures an image in a front direction of the display panel PN may be disposed under the first hole OA1 of the display panel PN. The image sensor (or the camera) may be disposed to overlap the first hole OA1 of the display panel PN. The image sensor (or the camera) receives light (e.g., visible light) that has passed through the first hole OA1 of the display panel PN.

For example, an infrared sensor (or an infrared camera) for facial recognition may be disposed under the second hole OA2 of the display panel PN. The infrared sensor (or the infrared camera) may be disposed to overlap the second hole OA2 of the display panel PN. The infrared sensor (or the infrared camera) receives light (e.g., infrared light) that has passed through the second hole OA2 of the display panel PN.

Conversely, the infrared sensor (or the infrared camera) for the facial recognition may be disposed under the first hole OA1 of the display panel PN and the image sensor (or the camera) that captures the image in the front direction of the display panel PN may be disposed under the second hole OA2 of the display panel PN.

A size of the second hole OA2 may be greater than a size of the first hole OA1. The first hole OA1 may be circular, for example. The second hole OA2 may have a predetermined width, for example, in the first direction parallel to the X-axis direction. Ends spaced apart from each other in the first direction of the second hole OA2 may have a curved shape.

An infrared light source may be additionally disposed under the second hole OA2, which is larger than the first hole OA1.

The cover member CG may be disposed on the display panel PN to cover a front surface of the display panel PN and may protect the display panel PN from an external impact. The cover member CG may have a larger area than the display panel PN.

For example, the cover member CG may be made of a transparent plastic material or a transparent glass material, but the present disclosure may not be limited thereto.

The cover member CG may include a display area that overlaps the display area AA of the display panel PN and a bezel area that overlaps the non-display area NAA of the display panel PN. The bezel area of the cover member CG may have a larger area than the non-display area NAA of the display panel PN.

The sealing member ECR may be disposed on the bezel area of the cover member CG and may be disposed in a shape of surrounding the four side surfaces of the display panel PN along the edge of the cover member CG. For example, the sealing member ECR may be disposed in a shape of surrounding the upper side surface PNT, the lower side surface PNB, the left side surface PNL, and the right side surface PNR of the display panel PN. The sealing member ECR may prevent foreign substances, moisture, and the like from penetrating into the display panel PN.

For example, the sealing member ECR may include an ultraviolet light (UV)-curable or a thermo-curable resin. The sealing member ECR may include, for example, an ultraviolet light (UV)-curable acrylic resin or an ultraviolet light (UV)-curable epoxy resin, but the present disclosure may not be limited thereto.

The stress relief member TSR may be disposed between the sealing member ECR and the display panel PN in an area adjacent to the first hole OA1 and the second hole OA2 of the display panel PN. The stress relief member TSR may be disposed adjacent to the upper side surface PNT of the display panel PN.

The sealing member ECR may be in contact with the four side surfaces of the display panel PN, excluding the area where the stress relief member TSR is disposed.

For example, the stress relief member TSR may include an ultraviolet light (UV)-curable or a thermo-curable resin. The stress relief member TSR may include, for example, an ultraviolet light (UV)-curable acrylic resin or an ultraviolet light (UV)-curable epoxy resin, but the present disclosure may not be limited thereto.

The stress relief member TSR may have a lower thermal expansion coefficient than the sealing member ECR. For example, the thermal expansion coefficient of the stress relief member TSR may correspond to 1/10 to 1/1000 of the thermal expansion coefficient of the sealing member ECR. For example, the thermal expansion coefficient of the stress relief member TSR may correspond to 1/10 to 1/500 of the thermal expansion coefficient of the sealing member ECR. For example, the thermal expansion coefficient of the stress relief member TSR may correspond to 1/10 to 1/100 of the thermal expansion coefficient of the sealing member ECR. For example, the thermal expansion coefficient of the stress relief member TSR may correspond to 1/50 to 1/250 of the thermal expansion coefficient of the sealing member ECR. For example, the thermal expansion coefficient of the stress relief member TSR may correspond to 1/50 to 1/100 of the thermal expansion coefficient of the sealing member ECR.

The stress relief member TSR may relieve stress applied to an area adjacent to the upper side surface PNT of the display panel PN because of thermal expansion and contraction of the sealing member ECR. In particular, the stress relief member TSR may relieve stress applied to an area around at least one hole, for example, the first hole OA1 and the second hole OA2 of the display panel PN, because of the thermal expansion and contraction of the sealing member ECR.

Accordingly, deformation around the at least one hole of the display panel PN caused by the thermal expansion and contraction of the sealing member ECR may be reduced or prevented, and cracks created around the at least one hole of the display panel PN may be prevented from growing and spreading.

As a result, a screen defect of the display device caused by penetration of the moisture and corrosion or electric corrosion of a wiring via the cracks created around the at least one hole of the display panel PN may be prevented.

In addition, the display device 100 may further include a support plate MP disposed under the display panel PN, an internal frame FM disposed under the support plate MP and in contact with the sealing member ECR and the stress relief member TSR, and a flexible printed circuit substrate FPCB connected to the display panel PN.

The support plate MP and the internal frame FM may have at least one hole corresponding to the at least one hole of the display panel PN. For example, the support plate MP and the internal frame FM may have first and second holes corresponding to the first hole OA1 and the second hole OA2 of the display panel PN.

The support plate MP may include a metal material. For example, the support plate MP may include stainless steel. The internal frame FM may include a plastic material. For example, the internal frame FM may include polycarbonate.

The sealing member ECR may be disposed in a shape of surrounding the four side surfaces of the support plate MP.

A plurality of wirings for operating the display panel PN may be disposed and at least one driving circuit chip may be mounted on the flexible printed circuit substrate FPCB. The flexible printed circuit substrate FPCB may be connected to at least one pad disposed in the non-display area of the display panel PN.

In addition, the display device 100 according to an embodiment of the present disclosure may further include a polarizing member disposed between the cover member CG and the display panel PN, and a back plate disposed between the display panel PN and the support plate MP. These will be described later.

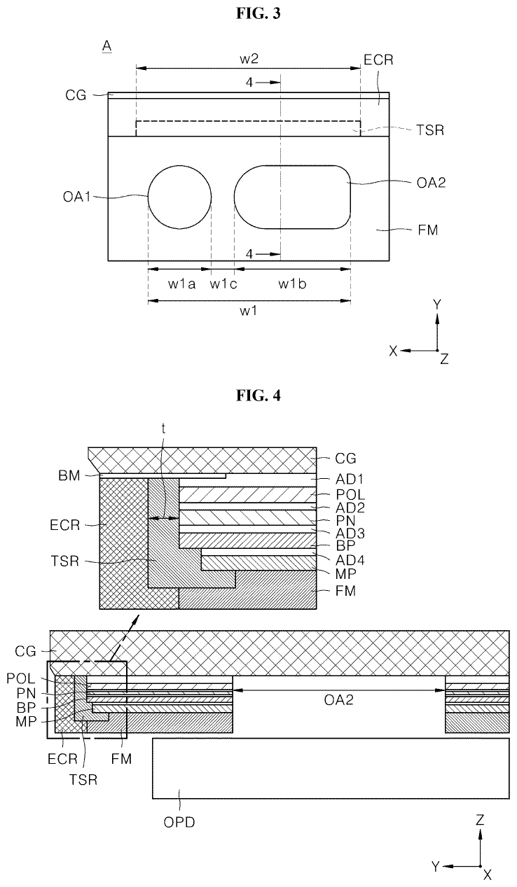

FIG. 3 is an enlarged view of A in FIG. 2 according to one embodiment. FIG. 4 is a cross-sectional view taken along a line 4-4 in FIG. 3 according to one embodiment.

Referring to FIGS. 3 and 4, a display device according to an embodiment of the present disclosure may include the display panel PN, a polarizing member POL disposed on the display panel PN, the cover member CG disposed on the polarizing member POL, a back plate BP disposed under the display panel PN, the support plate MP disposed under the back plate BP, and the internal frame FM disposed under the support plate MP. An optical element OPD may be disposed under the internal frame FM. The optical element OPD may include an image sensor or an infrared sensor.

The sealing member ECR may support the edge of the cover member CG and may surround the side surface of the display panel PN, a side surface of the back plate BP, and side surfaces of the support plate MP. Additionally, the stress relief member TSR may be disposed between the sealing member ECR and the display panel PN, between the sealing member ECR and the back plate BP, and between the sealing member ECR and the support plate MP. The stress relief member TSR may cover a portion of a lower surface of the support plate MP. The stress relief member TSR may be inserted between the portion of the lower surface of the support plate MP and a protrusion of the internal frame FM.

The sealing member ECR may cover side surfaces of the stress relief member TSR and cover at least a portion of a lower surface of the stress relief member TSR.

The polarizing member POL, the back plate BP, the support plate MP, and the internal frame FM may have at least one hole corresponding to the at least one hole of the display panel PN. For example, the polarizing member POL, the back plate BP, the support plate MP, and the internal frame FM may have first and second holes corresponding to the first hole OA1 and the second hole OA2 of the display panel PN.

The polarizing member POL, as a circularly polarizing plate for blocking external light, may include a retardation layer and a linear polarization layer attached to an outer surface of a protective film.

The back plate BP may have certain strength and thickness to complement rigidity of the display panel PN. The back plate BP may be made of rigid plastic. For example, the back plate BP may be made of polyethylene terephthalate (PET), polyimide (PI), polyethylene naphthalate (PEN), and the like, but the present disclosure may not be limited thereto.

A first adhesive layer AD1 may be disposed between the cover member CG and the polarizing member POL and a second adhesive layer AD2 may be disposed between the polarizing member POL and the display panel PN. A third adhesive layer AD3 may be disposed between the display panel PN and the back plate BP and a fourth adhesive layer AD4 may be disposed between the back plate BP and the support plate MP.

The first to fourth adhesive layers AD1, AD2, AD3, and AD4 may be in contact with the stress relief member TSR.

The first to fourth adhesive layers AD1, AD2, AD3, and AD4 may have at least one hole corresponding to the at least one hole of the display panel PN. For example, the first to fourth adhesive layers AD1, AD2, AD3, and AD4 may have first and second holes corresponding to the first hole OA1 and the second hole OA2 of the display panel PN.

The first to fourth adhesive layers AD1, AD2, AD3, and AD4 may be made of adhesive materials. The first to fourth adhesive layers AD1, AD2, AD3, and AD4 may be made of materials such as an optical clear adhesive (OCA), an optical clear resin (OCR), a pressure sensitive adhesive (PSA), or the like, but the present disclosure may not be limited thereto.

The stress relief member TSR may be disposed between the sealing member ECR and the display panel PN in an area adjacent to the at least one hole of the display panel PN. The stress relief member TSR may be disposed adjacent to the upper side surface PNT of the display panel PN. A width w2 of the stress relief member TSR may be greater than a size or a diameter of the at least one hole of the display panel PN.

For example, when the display panel PN includes the first hole OA1 and the second hole OA2 spaced apart from each other in the direction parallel to the upper side surface PNT of display panel PN, the width w2 of the stress relief member TSR may be greater than a sum w1 of a width w1a of the first hole OA1, a width w1b of the second hole OA2, and a gap wlc between the first hole OA1 and the second hole OA2.

The width w2 of the stress relief member TSR, the width w1a of the first hole OA1, the width w1b of the second hole OA2, and the gap wlc between the first hole OA1 and the second hole OA2 may be values measured in the first direction parallel to the upper side surface PNT of the display panel PN.

A thickness t of the stress relief member TSR may be constant along the direction parallel to the upper side surface PNT of the display panel PN. The thickness t of the stress relief member TSR may be a value measured in the second direction perpendicular to the upper side surface PNT of the display panel PN at a location adjacent to the upper side surface PNT of the display panel PN.

In an embodiment, when the display panel PN includes the first hole OA1 and the second hole OA2 spaced apart from each other, a thickness of a portion of the stress relief member TSR adjacent to an area between the first hole OA1 and the second hole OA2 may be greater than a thickness of another portion of the stress relief member TSR.

The stress applied to the area around the at least one hole, for example, the first hole OA1 and the second hole OA2 resulted from the thermal expansion and contraction of the sealing member ECR may be relieved by placing the stress relief member TSR with the lower thermal expansion coefficient than the sealing member ECR to have a width greater than the size or the diameter of the at least one hole.

The display device 100 may further include a light blocking pattern BM disposed on the bezel area of the cover member CG. The light blocking pattern BM may be disposed on a lower surface of the cover member CG and block various circuits, wirings, and various structures disposed in the non-display area NA of the display panel 110 from being viewed by a user. The light blocking pattern BM may be made of a material that may absorb light. The light blocking pattern BM may also be formed by printing black ink, but the present disclosure may not be limited thereto.

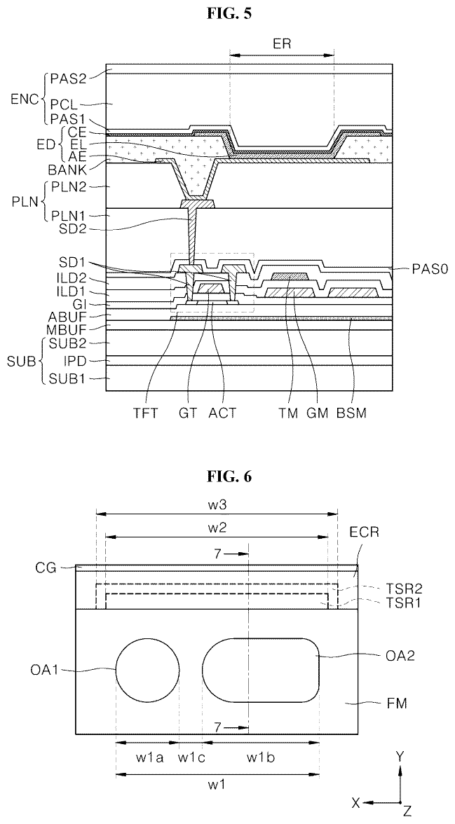

FIG. 5 is a cross-sectional view schematically showing a sub-pixel of a display device according to an embodiment of the present disclosure.

Referring to FIG. 5, the substrate SUB may include a first substrate SUB1, an intermediate insulating film IPD, and a second substrate SUB2. The intermediate insulating film IPD may be located between the first substrate SUB1 and the second substrate SUB2. As the substrate SUB is composed of the first substrate SUB1, the intermediate insulating film IPD, and the second substrate SUB2, the moisture penetration may be prevented. For example, the first substrate SUB1 and the second substrate SUB2 may be polyimide (PI) substrates. For example, the intermediate insulating film IPD may be made of an inorganic material.

The multi-buffer layer MBUF may be disposed on the second substrate SUB2 and the light blocking layer BSM that blocks light may be disposed on the multi-buffer layer MBUF. For example, the multi-buffer layer MBUF may be formed of a single layer or multiple layers of inorganic materials. For example, the light blocking layer BSM may be formed of a single layer or multiple layers of metal materials.

The active buffer layer ABUF may be disposed on the light blocking layer BSM. An active layer ACT of a thin film transistor TFT may be disposed on the active buffer layer ABUF. For example, the active buffer layer ABUF may be formed of a single layer or multiple layers of inorganic materials. For example, the active layer ACT may be made of a semiconductor material.

A gate insulating film GI may be disposed while covering the active layer ACT. For example, the gate insulating film GI may be formed of a single layer or multiple layers of inorganic materials.

A gate electrode GATE of the thin film transistor TFT may be disposed on the gate insulating film GI. In this regard, a gate material layer GM may be disposed on the gate insulating film GI along with the gate electrode GATE of the thin film transistor TFT at a location different from a formation location of the thin film transistor TFT. For example, each of the gate electrode GATE and the gate material layer GM may be formed of a single layer or multiple layers of metal materials.

A first interlayer insulating film ILD1 may be disposed while covering the gate electrode GATE and the gate material layer GM. A metal pattern TM may be disposed on the first interlayer insulating film ILD1. The metal pattern TM may be located at a location different from the formation location of the thin film transistor TFT. A second interlayer insulating film ILD2 may be disposed while covering the metal pattern TM on the first interlayer insulating film ILD1. For example, each of the first interlayer insulating film ILD1 and the second interlayer insulating film ILD2 may be formed of a single layer or multiple layers of inorganic or organic materials. For example, the metal pattern TM may be formed of a single layer or multiple layers of metal materials.

Two first source-drain electrode patterns SD1 may be disposed on the second interlayer insulating film ILD2. One of the two first source-drain electrode patterns SD1 may be a source electrode of the thin film transistor TFT and the other may be a drain electrode of the thin film transistor TFT. For example, the first source-drain electrode patterns SD1 may be formed of a single layer or multiple layers of metal materials.

The two first source-drain electrode patterns SD1 may be electrically connected to one side and the other of the active layer ACT via contact holes extending through the second interlayer insulating film ILD2, the first interlayer insulating film ILD1, and the gate insulating film GI.

A passivation layer PAS0 is disposed while covering the two first source-drain electrode patterns SD1. For example, the passivation layer PAS0 may be formed of a single layer or multiple layers of inorganic materials.

A planarization layer PLN may be disposed on the passivation layer PAS0.

The planarization layer PLN may include a first planarization layer PLN1 and a second planarization layer PLN2. For example, each of the first planarization layer PLN1 and the second planarization layer PLN2 may be formed of a single layer or multiple layers of organic materials.

The first planarization layer PLN1 may be disposed on the passivation layer PAS0.

A second source-drain electrode pattern SD2 may be disposed on the first planarization layer PLN1. The second source-drain electrode pattern SD2 may be connected to one of the two first source-drain electrode patterns SD1 via a contact hole extending through the first planarization layer PLN1. The second source-drain electrode pattern SD2 may be a connecting electrode. For example, the second source-drain electrode pattern SD2 may be formed of a single layer or multiple layers of metal materials.

The second planarization layer PLN2 may be disposed while covering the second source-drain electrode pattern SD2. A light emitting element ED may be disposed on the second planarization layer PLN2.

A stacked structure of the light emitting element ED will be described. An anode electrode AE may be disposed on the second planarization layer PLN2. The anode electrode AE may be electrically connected to the second source-drain electrode pattern SD2 via a contact hole extending through the second planarization layer PLN2. For example, the anode electrode AE may be made of a metal material, a transparent conductive oxide, or a combination thereof.

A bank BANK may be disposed while covering a portion of the anode electrode AE. A portion of the bank BANK corresponding to a light emitting area ER of a sub-pixel SP may be removed. For example, the bank BANK may be made of an inorganic or organic material.

A portion of the anode electrode AE may be exposed by an opening of the bank BANK. The light emitting layer EL may be located at an opening of the bank BANK and on a side surface of the bank BANK.

At the opening of the bank BANK, the light emitting layer EL may be in contact with the anode electrode AE. A cathode electrode CE may be disposed on the light emitting layer EL and the bank BANK. For example, the cathode electrode CE may be made of a metal material, a transparent conductive oxide, or a combination thereof.

The light emitting element ED may be formed by the anode electrode AE, the light emitting layer EL, and the cathode electrode CE. The light emitting layer EL may include at least one organic light emitting material.

An encapsulation layer ENC that may minimize or block external moisture or oxygen from penetrating into the light emitting element ED may be disposed on the light emitting element ED.

The encapsulation layer ENC may have a single-layer structure or a multi-layer structure. For example, as shown in FIG. 5, the encapsulation layer ENC may include a first encapsulation layer PAS1, a second encapsulation layer PCL, and a third encapsulation layer PAS2. For example, the first encapsulation layer PAS1 and the third encapsulation layer PAS2 may be inorganic films and the second encapsulation layer PCL may be an organic film. Among the first encapsulation layer PAS1, the second encapsulation layer PCL, and the third encapsulation layer PAS2, the second encapsulation layer PCL may be the thickest and may serve as a planarization layer.

The first encapsulation layer PAS1 may be disposed on the cathode electrode CE and may be disposed closest to the light emitting element ED. For example, the first encapsulation layer PAS1 may be made of an inorganic material such as silicon nitride (SiNx), silicon oxide (SiOx), silicon oxynitride (SiON), or aluminum oxide (Al₂O₃).

The second encapsulation layer PCL may be disposed on the first encapsulation layer PAS1. For example, the second encapsulation layer PCL may be made of an organic material such as acrylic resin, epoxy resin, polyimide, polyethylene, or silicon oxycarbon (SiOC).

The third encapsulation layer PAS2 may be disposed on the second encapsulation layer PCL. For example, the third encapsulation layer PAS2 may be made of an inorganic material such as silicon nitride (SiNx), silicon oxide (SiOx), silicon oxynitride (SiON), or aluminum oxide (Al2O3).

A touch sensor and a protective layer to protect the same may be further disposed on the encapsulation layer ENC.

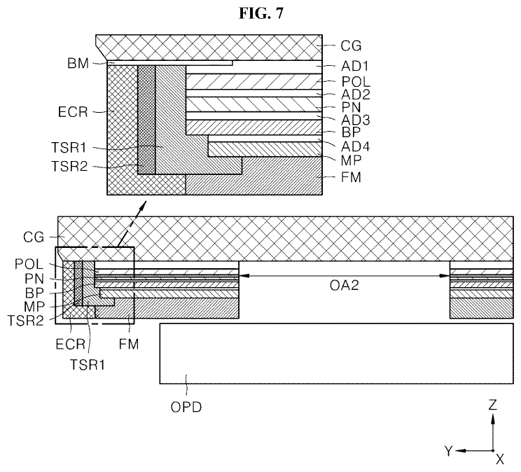

FIG. 6 is a diagram corresponding to FIG. 3 and schematically shows a display device according to another embodiment of the present disclosure. FIG. 7 is a cross-sectional view taken along a line 7-7 in FIG. 6 according to one embodiment. When describing FIGS. 6 and 7, descriptions redundant with the display device in FIGS. 3 and 4 will be omitted.

Referring to FIGS. 6 and 7, a display device 100-1 according to another embodiment of the present disclosure, unlike the display device 100 in FIGS. 1 to 4, includes a first stress relief member TSR1 and a second stress relief member TSR2.

The first stress relief member TSR1 may be disposed between the sealing member ECR and the display panel PN in the area adjacent to the at least one hole for example, the first hole OA1 and the second hole OA2, of the display panel PN. The first stress relief member TSR1 may be disposed adjacent to the upper side surface PNT of the display panel PN.

The second stress relief member TSR2 may be disposed between the sealing member ECR and the first stress relief member TSR1. The second stress relief member TSR2 may surround side surfaces of the first stress relief member TSR1.

The sealing member ECR may be in contact with the four side surfaces of the display panel PN, excluding an area in which the first and second stress relief members TSR1 and TSR2 are disposed.

For example, the first and second stress relief members TSR1 and TSR2 may include an ultraviolet light (UV)-curable or thermos-curable resin. The first and second stress relief members TSR1 and TSR2 may include, for example, an ultraviolet light (UV)-curable acrylic resin or an ultraviolet light (UV)-curable epoxy resin, but the present disclosure may not be limited thereto.

The first and second stress relief members TSR1 and TSR2 may have lower thermal expansion coefficients than the sealing member ECR. For example, the thermal expansion coefficients of the first and second stress relief members TSR1 and TSR2 may correspond to 1/10 to 1/1000 of the thermal expansion coefficient of the sealing member ECR. For example, the thermal expansion coefficients of the first and second stress relief members TSR1 and TSR2 may correspond to 1/10 to 1/500 of the thermal expansion coefficient of the sealing member ECR. For example, the thermal expansion coefficients of the first and second stress relief members TSR1 and TSR2 may correspond to 1/10 to 1/100 of the thermal expansion coefficient of the sealing member ECR. For example, the thermal expansion coefficients of the first and second stress relief members TSR1 and TSR2 may correspond to 1/50 to 1/250 of the thermal expansion coefficient of the sealing member ECR. For example, the thermal expansion coefficients of the first and second stress relief members TSR1 and TSR2 may correspond to 1/50 to 1/100 of the thermal expansion coefficient of the sealing member ECR.

A thermal expansion coefficient of the second stress relief member TSR2 may be higher than that of the first stress relief member TSR1 and lower than that of the sealing member ECR.

A width w2 of the first stress relief member TSR1 may be greater than the size or the diameter of the at least one hole of the display panel PN.

For example, when the display panel PN includes the first hole OA1 and the second hole OA2 spaced apart from each other in the direction parallel to the upper side surface PNT of the display panel PN, the width w2 of the first stress relief member TSR1 may be greater than the sum w1 of the width w1a of the first hole OA1, the width w1b of the second hole OA2, and the gap wlc between the first hole OA1 and the second hole OA2.

A width w3 of the second stress relief member TSR2 may be greater than the width w2 of the first stress relief member TSR1.

The width w2 of the first stress relief member TSR1, the width w3 of the second stress relief member TSR2, the width w1a of the first hole OA1, the width w1b of the second hole OA2, and the gap wlc between the first hole OA1 and the second hole OA2 may be values measured in the first direction parallel to the upper side surface PNT of the display panel PN.

As the first and second stress relief members TSR1 and TSR2 having the lower thermal expansion coefficients than the sealing member ECR are disposed to have widths greater than the size or the diameter of the at least one hole, the stress applied to the area adjacent to the at least one hole, for example, the first hole OA1 and the second hole OA2, of the display panel PN resulted from the thermal expansion and contraction of the sealing member ECR may be relieved.

Therefore, the deformation around the first hole OA1 and the second hole OA2 of the display panel PN resulted from the thermal expansion and contraction of the sealing member ECR may be reduced or prevented, and the cracks created around the at least one hole of the display panel PN may be prevented from growing and spreading.

As a result, the screen defect of the display device caused by the penetration of the moisture and the corrosion or the electric corrosion of the wiring via the cracks created around the at least one hole of the display panel PN may be prevented.

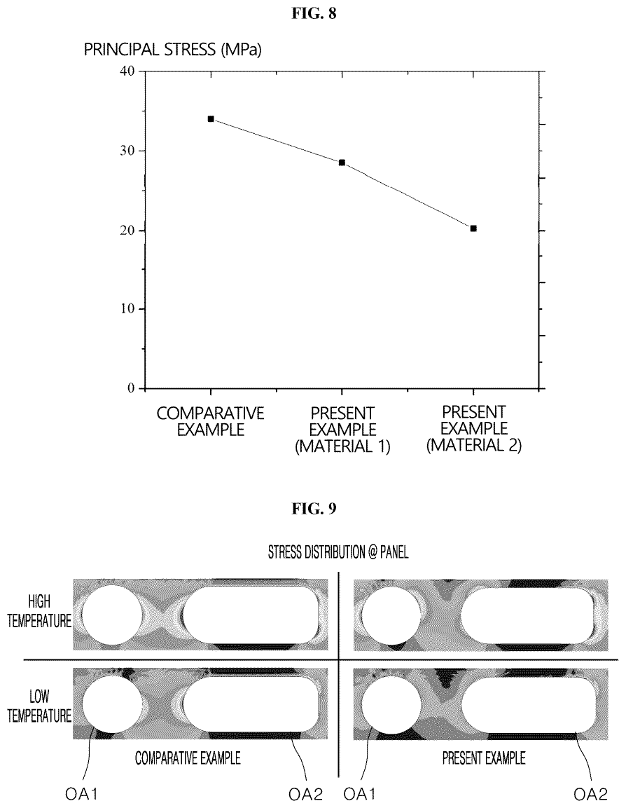

FIG. 8 is a graph showing principal stress applied to an area around a hole of a display device according to Comparative Example and Present Examples. FIG. 9 is a graph showing stress distribution of an area around a hole of a display device according to Comparative Example and Present Example. FIGS. 8 and 9 show results of performing stress simulation on the display device 100 in FIGS. 1 to 5.

Referring to FIG. 8, it may be seen that the principal stress applied to the area around the hole of the display device is lower in Present Examples compared to Comparative Example. It may be seen that the principal stress applied to the area around the hole of the display device in Present Example (material 1) is about 9% lower and the principal stress applied to the area around the hole of the display device in Present Example (material 2) is about 37% lower than that in Comparative Example. FIG. 8 shows the principal stress values at a specific point around the hole, but in the case of Present Examples, the principal stress applied to the area around the hole was overall reduced compared to that in Comparative Example.

Comparative Example in FIG. 8 is a case that does not include the stress relief member. In FIG. 8, Present Example (material 1) is a case in which the stress relief member TSR is disposed between the sealing member ECR and the display panel PN in the area adjacent to the first hole OA1 and the second hole OA2 of the display panel PN and a thermal expansion coefficient of the stress relief member TSR is 1/10 of the thermal expansion coefficient of the sealing member ECR. In FIG. 8, Present Example (material 2) is a case in which the stress relief member TSR is disposed between the sealing member ECR and the display panel PN in the area adjacent to the first hole OA1 and the second hole OA2 of the display panel PN and a thermal expansion coefficient of the stress relief member TSR is 1/100 of the thermal expansion coefficient of the sealing member ECR.

Referring to FIG. 9, it may be seen that the stress applied to the area around the first hole OA1 and the second hole OA2 of the display panel in Present Example is lower than that in Comparative Example at low and high temperatures. The low temperature may be any temperature above −40° C. and below −5° C., and the high temperature may be any temperature above 50° C. and below 90° C. It may be seen that the stress especially between the first hole OA1 and the second hole OA2 in Present Example is noticeably lower than that in Comparative Example. FIG. 9 shows that the stress gradually increases from blue to red. Present Example in FIG. 9 corresponds to Present Example (material 2) in FIG. 8.

A display device according to embodiments of the present disclosure may be described as follows.

A display device according to an embodiment of the present disclosure includes a display panel including at least one hole defined in a display area, a cover member disposed on the display panel, a sealing member supporting an edge of the cover member and surrounding side surfaces of the display panel, and a stress relief member disposed adjacent to the at least one hole and disposed between the sealing member and a side surface of the display panel.

According to an embodiment of the present disclosure, a thermal expansion coefficient of the stress relief member may be lower than a thermal expansion coefficient of the sealing member.

According to an embodiment of the present disclosure, a width of the stress relief member may be greater than a width of the at least one hole in a direction parallel to an upper side surface of the display panel.

According to an embodiment of the present disclosure, the at least one hole may include a first hole and a second hole spaced apart from each other, and a width of the stress relief member may be greater than a sum of a width of the first hole, a width of the second hole, and a gap between the first hole and the second hole in a first direction parallel to an upper side surface of the display panel.

According to an embodiment of the present disclosure, the at least one hole may include a first hole and a second hole spaced apart from each other, and a thickness of a portion of the stress relief member adjacent to an area between the first hole and the second hole may be greater than another portion of the stress relief member.

According to an embodiment of the present disclosure, the stress relief member may be a first stress relief member, and the display device may further include a second stress relief member disposed between the sealing member and the first stress relief member.

According to an embodiment of the present disclosure, a thermal expansion coefficient of the second stress relief member may be higher than a thermal expansion coefficient of the first stress relief member and lower than a thermal expansion coefficient of the sealing member.

According to an embodiment of the present disclosure, a width of the second stress relief member may be greater than a width of the first stress relief member.

According to an embodiment of the present disclosure, the display device may further include a polarizing plate disposed on the display panel, a back plate disposed under the panel, and a metal plate disposed under the back plate, and the stress relief member may be in contact with the side surface of the display panel, a side surface of the polarizing plate, a side surface of the back plate, and a side surface of the metal plate.

A display device according to an embodiment of the present disclosure includes a display panel including at least one hole defined in a display area, a sealing member surrounding side surfaces of the display panel, and at least one stress relief member disposed adjacent to the at least one hole and disposed between the sealing member and a side surface of the display panel, wherein the stress relief member has a thermal expansion coefficient lower than a thermal expansion coefficient of the sealing member.

According to an embodiment of the present disclosure, the at least one stress relief member may include a first stress relief member having a thermal expansion coefficient lower than the thermal expansion coefficient of the sealing member, and a second stress relief member having a thermal expansion coefficient higher than the thermal expansion coefficient of the first stress relief member and lower than the thermal expansion coefficient of the sealing member.

According to an embodiment of the present disclosure, a width of the at least one stress relief member may be greater than a width of the at least one hole in a direction parallel to an upper side surface of the display panel.

According to an embodiment of the present disclosure, the at least one hole may include a first hole and a second hole spaced apart from each other, and a width of the at least one stress relief member may be greater than a sum of a width of the first hole, a width of the second hole, and a gap between the first hole and the second hole in a first direction parallel to an upper side surface of the display panel.

As described above, the present disclosure is described with reference to illustrative drawings, but the present disclosure is not limited by the embodiments and drawings disclosed in the present disclosure.

It is obvious that various modifications may be made by a person skilled in the art within the scope of the technical idea of the present disclosure.

In addition, even when the effects of the configuration of an embodiment of the present disclosure were not explicitly described and explained earlier while describing an embodiment of the present disclosure, it is natural that the predictable effects of the configuration should also be recognized. Although the embodiments of the present disclosure have been described in more detail with reference to the accompanying drawings, the present disclosure is not necessarily limited to these embodiments, and may be modified in a various manner within the scope of the technical spirit of the present disclosure. Accordingly, the embodiments as disclosed in the present disclosure are intended to describe rather than limit the technical idea of the present disclosure, and the scope of the technical idea of the present disclosure is not limited by these embodiments. Therefore, it should be understood that the embodiments described above are not restrictive but illustrative in all respects.

What is claimed is:

1. A display device comprising:
a display panel including at least one hole in a display area of the display panel;
a cover member on the display panel;
a sealing member supporting an edge of the cover member and surrounding side surfaces of the display panel; and
a stress relief member adjacent to the at least one hole and between the sealing member and a side surface of the side surfaces of the display panel.

2. The display device of claim 1, wherein a thermal expansion coefficient of the stress relief member is lower than a thermal expansion coefficient of the sealing member.

3. The display device of claim 1, wherein a width of the stress relief member is greater than a width of the at least one hole in a direction parallel to an upper side surface of the display panel.

4. The display device of claim 1, wherein the at least one hole includes a first hole and a second hole spaced apart from the first hole,
wherein a width of the stress relief member is greater than a sum of a width of the first hole, a width of the second hole, and a gap between the first hole and the second hole in a first direction parallel to an upper side surface of the display panel.

5. The display device of claim 1, wherein the at least one hole includes a first hole and a second hole spaced apart from the first hole,
wherein a thickness of a portion of the stress relief member adjacent to an area between the first hole and the second hole is greater than another portion of the stress relief member.

6. The display device of claim 1, wherein the stress relief member is a first stress relief member and the display device further includes a second stress relief member between the sealing member and the first stress relief member.

7. The display device of claim 6, wherein a thermal expansion coefficient of the second stress relief member is higher than a thermal expansion coefficient of the first stress relief member and lower than a thermal expansion coefficient of the sealing member.

8. The display device of claim 6, wherein a width of the second stress relief member is greater than a width of the first stress relief member.

9. The display device of claim 1, further comprising:
a polarizing plate on the display panel;
a back plate under the display panel; and
a metal plate under the back plate,
wherein the stress relief member is in contact with the side surface of the display panel, a side surface of the polarizing plate, a side surface of the back plate, and a side surface of the metal plate.

10. A display device comprising:
a display panel including at least one hole in a display area of the display panel;
a sealing member surrounding side surfaces of the display panel; and
at least one stress relief member adjacent to the at least one hole and between the sealing member and a side surface of the side surfaces of the display panel,
wherein the at least one stress relief member has a thermal expansion coefficient that is lower than a thermal expansion coefficient of the sealing member.

11. The display device of claim 10, wherein the at least one stress relief member includes a first stress relief member having a thermal expansion coefficient that is lower than the thermal expansion coefficient of the sealing member, and a second stress relief member having a thermal expansion coefficient that is higher than the thermal expansion coefficient of the first stress relief member and lower than the thermal expansion coefficient of the sealing member.

12. The display device of claim 10, wherein a width of the at least one stress relief member is greater than a width of the at least one hole in a direction parallel to an upper side surface of the display panel.

13. The display device of claim 10, wherein the at least one hole includes a first hole and a second hole spaced apart from the first hole,
wherein a width of the at least one stress relief member is greater than a sum of a width of the first hole, a width of the second hole, and a gap between the first hole and the second hole in a first direction parallel to an upper side surface of the display panel.
